(19) United States
(12) Patent Application Publication
(10) Pub. No.: US 2008/0100310 A1
(43) Pub. Date: May 1, 2008

(54) Linearity Tuning Temperature Control Circuit

(75) Inventors: Qun Song, Sunnyvale, CA (US); Qi Wang, Shanghai (CN); Zeyu Huang, Shanghai (CN); Qi Xu, Shanghai (CN)

Correspondence Address: STUART T AUVINEN, 429 26TH AVENUE, SANTA CRUZ, CA, 95062-5319, US

(73) Assignee: PERICOM TECHNOLOGY (SHANGHAI) CO. LTD., San Jose, CA (US)

(21) Appl. No.: 11/871,005

(22) Filed: Oct. 11, 2007

(30) Foreign Application Priority Data
Oct. 27, 2006 (CN) 200620047208.X

(51) Int. Cl. G01R 27/08

(52) U.S. Cl. 324/713

(57) ABSTRACT

A linear heater control circuit has a more linear relationship between sensed temperature and a variable resistance. As the user adjusts the variable resistance, the temperature increases linearly rather than abruptly. The linear control circuit has a parallel resistor that is in parallel with the variable resistor and one or two series resistors that are in series with the variable resistor. The tap of the variable resistor is input to a comparator that compares the tap voltage to a reference voltage and adjusts a trigger to a Silicon-Controlled Rectifier (SCR). The SCR switches AC current to a heating element to increase its temperature. When the SCR switches off, temperature sensing is performed using a voltage network that includes the parallel resistor and the variable resistor. A switch or diode isolates the voltage network from the heating element during heating to protect the comparator.

### RELATED APPLICATION

This application claims the benefit under 35 USC § 119 of the co-pending application for “Linearity tuning temperature control circuit”, China App. No. 200620047208.X, filed Oct. 27, 2006.

### FIELD OF THE INVENTION

This invention relates to electrical heater control circuits, and more particularly to temperature control integrated circuits or modules.

### BACKGROUND OF THE INVENTION

A heating element with positive temperature coefficient may be produced from an alloy. The heating element may be a metal-ceramic heater, metal wire heater, etc, A positive temperature-coefficient heating element (hereinafter referred to a heating element) has a positive temperature coefficient, with the characteristic that with a rising temperature, its resistance rises linearly. So the heating element also can be used as temperature sensor element in a temperature control circuit. Separate temperature sensors are not needed, reducing cost.

FIG. 1 shows a traditional temperature control circuit. Power terminals L and N provide 110 VAC or 220 VAC power. Silicon Controlled Rectifier (SCR) 106 has a trigger input, signal C, that controls the power supply current through SCR 106. Temperature sampling switch 122 samples the voltage on the node between SCR 106 and heating element 108. VCC is the direct-current DC power supply input. Comparator 102 has an output that drives synchronization circuit 104 which generates trigger signal C that is the trigger input to SCR 106.

A temperature sampling and turning circuit includes series resistor 114, series resistor 110, parallel resistor 112 and adjustable resistor 120. A temperature setting circuit includes reference resistor 116 and reference resistor 118.

The resistance value of series resistor 114 is designed for heating element 108. Series resistor 110 has a resistance value to adjust for different temperature coefficients of heating element 108. Parallel resistor 112 is connected to variable resistor 120 in parallel to adjusts the temperature range.

The alloy resistor in heating element 108 has a resistance-temperature coefficient that is generally less than 4,900 ppm/° C. Therefore the difference between the maximum temperature and minimum temperature is not too large. Variable resistor 120 is used for temperature regulation. The resistance value of variable resistor 120 may be large, so parallel resistor parallel 112 reduces the overall effective resistance across the terminals variable resistor 120.

During the positive half cycles of the AC power, SCR 106 is triggered on to conduct current to heating element 108. During this heating time, temperature sampling switch 122 must be open to prevent the high voltage from the heating power supply from entering and damaging comparator 102.

Temperature sampling is executed during the negative half cycles of the AC heater power supply. Reference resistor 116 and reference resistor 118 divide the DC power supply VCC and generate reference voltage VT that is applied to the inverting input (−) of comparator 102. While the temperature signal is being sampled, temperature sampling switch 122 should be closed.

Series resistor 114, series resistor 110, and adjustable variable resistor 120 that is connected with parallel resistor 112 in parallel and heating element 108 form a voltage network that generates the temperature sense signal VS. Temperature sense signal VS is applied to the non-inverting (+) input of comparator 102.

Comparator 102 compares VS with VT, and the output of comparator 102 is transmitted to synchronization circuit 104, where it is synchronized with the alternating power. Synchronization circuit 104 generates the trigger signal C to control conduction through SCR 106. The circuit controls the heating power to maintain heating element 108 at the desired temperature.

While sampling temperature signal VS, the circuit has the equation below, where VR is the resistance of variable resistor 120, R3 is the resistance of series resistor 114, R4 is the resistance of series resistor 110, R5 is the resistance of parallel resistor 112, and H is the resistance of heating element 108:

VS=VCC×(H+R4+VR//R5)/(R3+VR//R5+R4+H)=VT Eqn. (1)

Assume that VT=0.5 VCC, that the maximum resistance VR of variable resistor 120 is 1000 ohm, and that heating element 108 has a uniform temperature-resistance rate. When the target minimum temperature of heating element 108 is 100° C., the resistance of heating element 108, H=45 ohm. The variable resistance at the minimum is set to VR=1000 ohm.

Alternately, when the target maximum temperature of heating element 108 is 200° C., H=60 ohm, and VR=0 ohm for the maximum setting. VR is a variable resistance that can vary from 0 to 1000 ohm. Other parameters can be calculated using these conditions in equation (1).

FIG. 2 shows a graph of a curve that indicates the relation between the variable resistor and the temperature of the heating element. The X-axis is the resistance value VR of variable resistor 120, which changes from 0 ohm to 1000 ohm. The Y-axis coordinates are the temperature of heating element 108 which changes from 200° C. to 100° C. FIG. 2 shows that the linearity between VR and temperature is very poor.

### BRIEF DESCRIPTION OF THE DRAWINGS

FIG. 1 shows a traditional temperature control circuit.

FIG. 2 shows a graph of a curve that indicates the relation between the variable resistor and the temperature of the heating element.

FIG. 3 shows a heater control circuit with a more linear relationship between the temperature of the heating element and the variable resistor value.

FIG. 4 shows a graph of a curve indicating the relationship between the variable resistor and the temperature of the heating element.

FIG. 5 is an alternate embodiment of a linear heater control circuit with a diode rectifier.

FIG. 6 is an alternate embodiment of a linear heater control circuit with a disconnected variable-resistor tap.

FIG. 7 is an alternate embodiment of a linear heater control circuit with one less series resistors.

### DETAILED DESCRIPTION

The present invention relates to an improvement in heater control circuits. The following description is presented to enable one of ordinary skill in the art to make and use the invention as provided in the context of a particular application and its requirements. Various modifications to the preferred embodiment will be apparent to those with skill in the art, and the general principles defined herein may be applied to other embodiments. Therefore, the present invention is not intended to be limited to the particular embodiments shown and described, but is to be accorded the widest scope consistent with the principles and novel features herein disclosed.

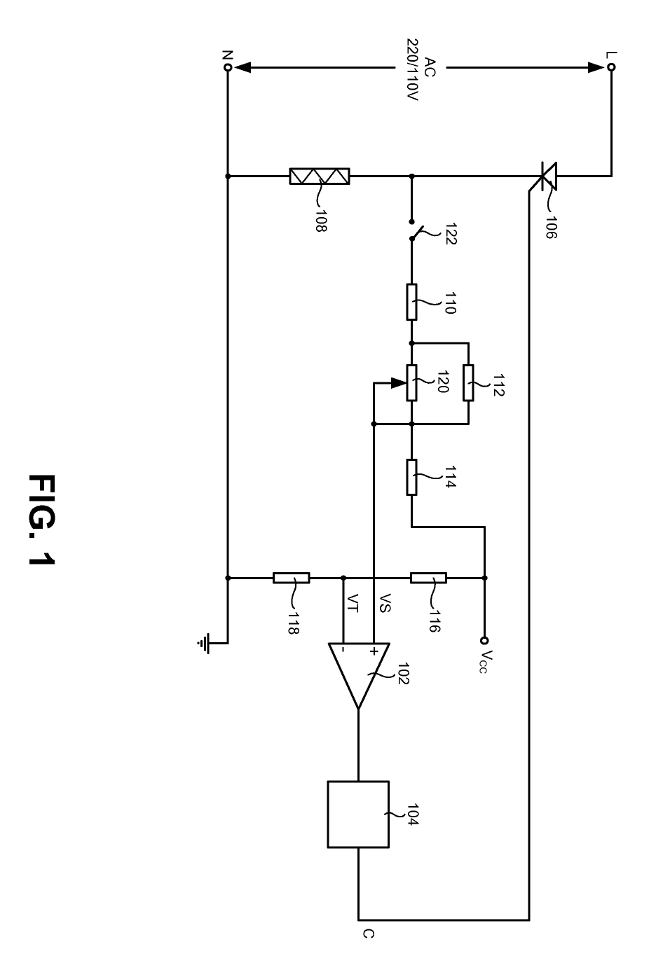

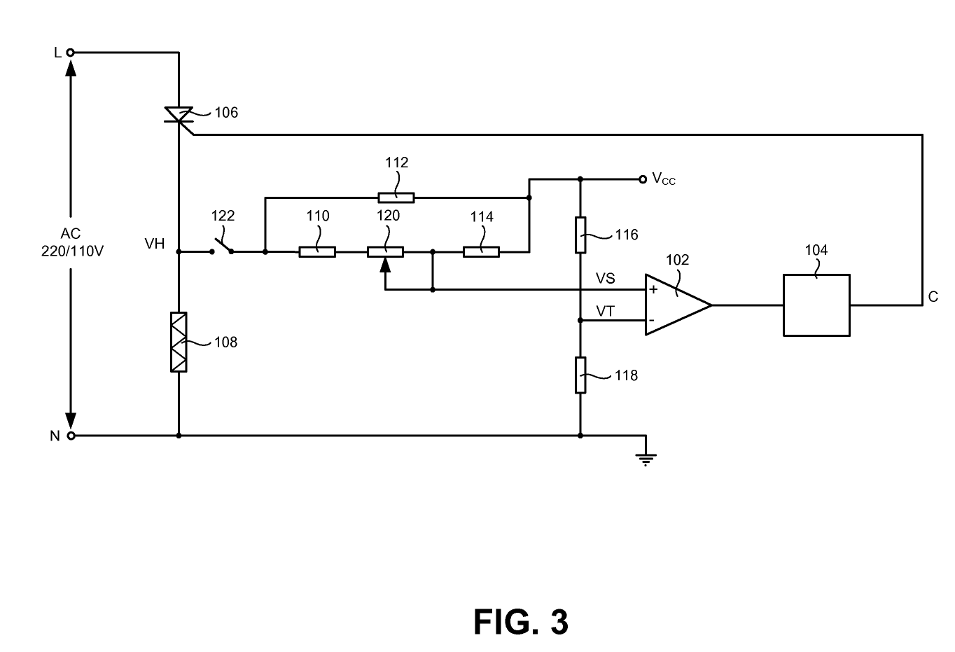

FIG. 3 shows a heater control circuit with a more linear relationship between the temperature of the heating element and the variable resistor value. Compared with the traditional temperature control circuit of FIG. 1, the more linear heater control circuit has parallel resistor 112 connect with series resistor 110, variable resistor 120 and series resistor 114 in parallel. Series resistor 110, variable resistor 120 and series resistor 114 form a potentiometer which divides the voltage between parallel resistor 112 and VS. The tap voltage of variable resistor 120 is applied to the input of comparator 102 as voltage VS. The tap voltage of variable resistor 120, VS, is also connected to the node between variable resistor 120 and series resistor 114.

A feature of this circuit is that the resistance value of parallel resistor 112 can be adapted to different resistance values of heating element 108 without affecting the linearity of voltage VS on the tap of variable resistor 120.

Series resistor 110 is used to adapt circuit for different temperature coefficients of heating element 108. Different resistance values of the variable resistor 120 can be chosen to suit the desired temperature range.

During sampling of the temperature signal, voltage VS, the system operates according to the equation below, where VR is the resistance of variable resistor 120, R3 is the resistance of series resistor 114, R4 is the resistance of series resistor 110, R5 is the resistance of parallel resistor 112, and H is the resistance of heating element 108:

VS=VH+□+VCC−VH□×□R4+VR□/□R4+VR+R3□=VT Eqn.(2)

VH is the voltage on the upper terminal of heating element 108:

VH=VCC×H/(H+R5//(R4+VR+R3)) Eqn.(3)

Assume that VT=0.5 VCC, that the maximum resistance of variable resistor 120 is 1000 ohm, and that heating element 108 has a uniform temperature-resistance rate. When the target minimum temperature of heating element 108 is 100° C., and the resistance of heating element 108 is H=45 ohm, variable resistor 120 is set to its maximum value of VR=1000 ohm.

Alternately, when the target maximum temperature of heating element 108 is 200° C., and its resistance is H=60 ohm, variable resistor 120 is set to its minimum value of VR=0 ohm. Other parameters can be calculated by taking these conditions in to equations (2) and (3).

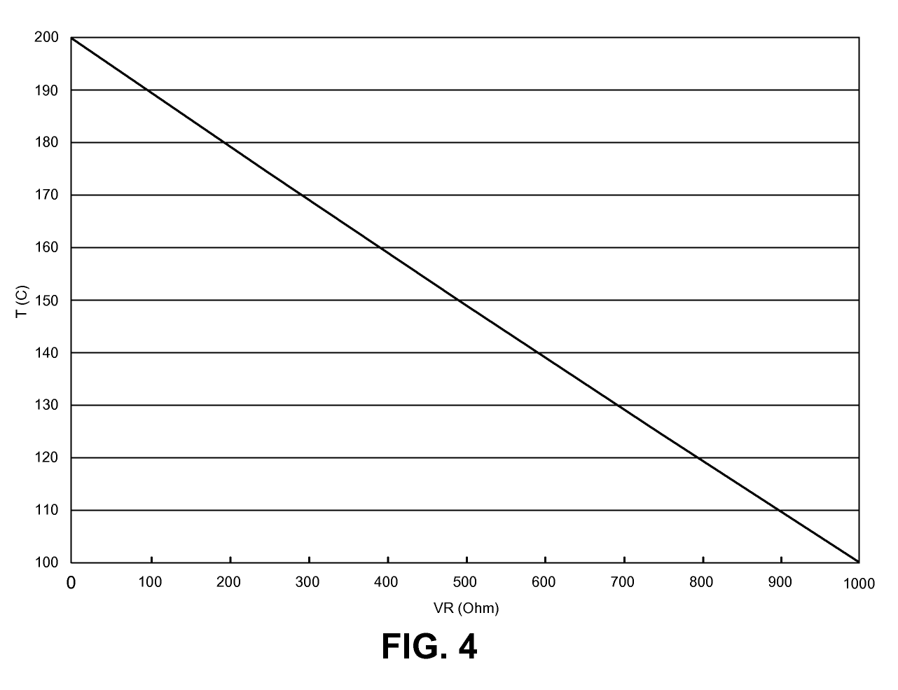

FIG. 4 shows a graph of a curve indicating the relationship between the variable resistor and the temperature of the heating element. The Y-axis (abscissa) is the resistance value of variable resistor 120, which changes from 0 ohm to 1000 ohm. This is the variable resistance to the tap terminal of variable resistor 120. The tap terminal may be moved along variable resistor 120, such as by a slider or knob that a user moves to vary the temperature of heating element 108 and the product.

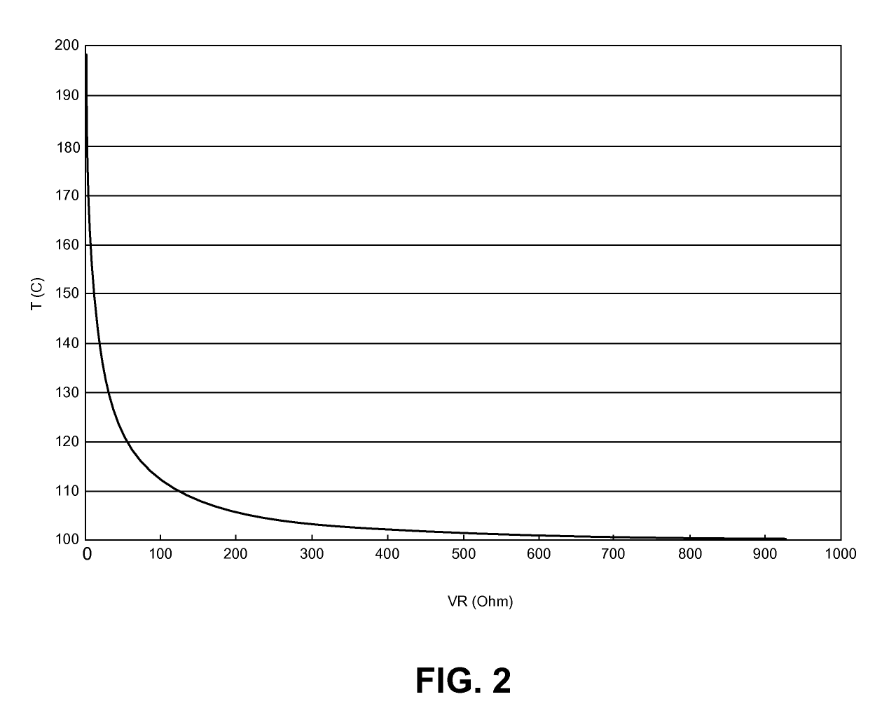

The X-axis (longitudinal coordinates) is the temperature of heating element 108, which changes from 200° C. to 100° C. As can be seen in FIG. 4, the linearity between variable resistor 120 and temperature is very good, especially in comparison to FIG. 2.

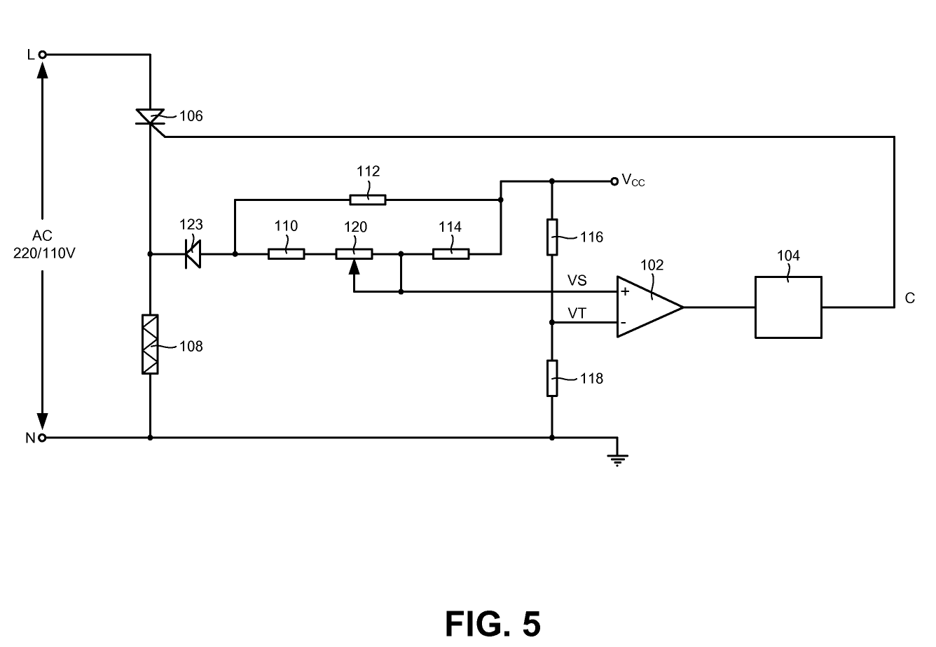

FIG. 5 is an alternate embodiment of a linear heater control circuit with a diode rectifier. Temperature sampling switch 122 (FIG. 3) is replaced by regulator diode 123. Regulator diode 123 prevents the high voltage of the heater power supply from reaching the input of comparator 102 during the positive half-cycles of the AC power. Diode 123 does not affect the temperature sampling during the negative half-cycles. Other components are similar to those described earlier.

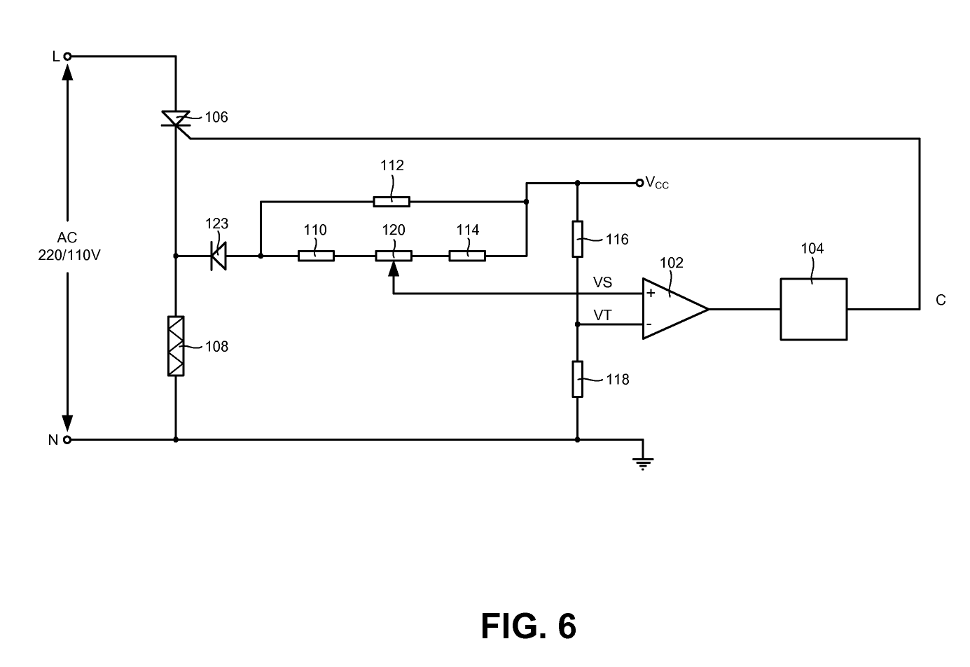

FIG. 6 is an alternate embodiment of a linear heater control circuit with a disconnected variable-resistor tap. The tap voltage of variable resistor 120, VS, is not connected to the node between variable resistor 120 and series resistor 114 in this alternate embodiment, as was the case in FIG. 3. Other components are similar to those described earlier.

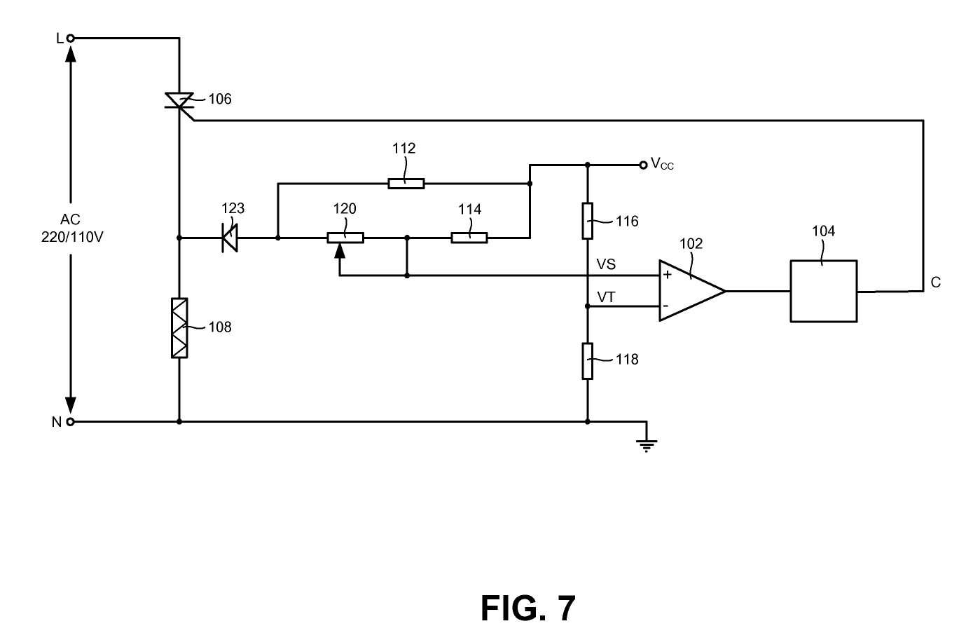

FIG. 7 is an alternate embodiment of a linear heater control circuit with one less series resistors. Series resistor 110 of FIG. 3 is removed to form the alternate circuit of FIG. 7. Other components are similar to those described earlier.

### ALTERNATE EMBODIMENTS

Several other embodiments are contemplated by the inventors. Various components could be added or substituted, such as switches, diodes, additional resistors, bypass capacitors, filters, etc. The linear heating control circuit may be partially or fully integrated on a semiconductor integrated circuit (IC), with or without the SCR, while heating element 108 is external to the IC.

Series resistor 114, series resistor 110 and parallel resistor 112 can be composed of multiple resistors or of multiple equivalent resistors. The tap terminal of variable resistor 120 may connect to the first terminal or to the second terminal of variable resistor 120, or the tap terminal does not connect to either of the first terminal or the second terminal of variable resistor 120.

Temperature tuning may be continuous and uniform, since the user can adjust the variable resistance, such as by a rotating knob or slider connected to variable resistor 120, and have the temperature of the heating element increase or decrease linearly with the knob movement, rather than have small knob movements create surprisingly large and abrupt temperature changes as can occur with non-linear circuits.

The background of the invention section may contain background information about the problem or environment of the invention rather than describe prior art by others. Thus inclusion of material in the background section is not an admission of prior art by the Applicant.

Any methods or processes described herein are machine-implemented or computer-implemented and are intended to be performed by machine, computer, or other device and are not intended to be performed solely by humans without such machine assistance. Tangible results generated may include reports or other machine-generated displays on display devices such as computer monitors, projection devices, audio-generating devices, and related media devices, and may include hardcopy printouts that are also machine-generated. Computer control of other machines is another a tangible result.

Any advantages and benefits described may not apply to all embodiments of the invention. When the word “means” is recited in a claim element, Applicant intends for the claim element to fall under 35 USC Sect. 112, paragraph 6. Often a label of one or more words precedes the word “means”. The word or words preceding the word “means” is a label intended to ease referencing of claim elements and is not intended to convey a structural limitation. Such means-plus-function claims are intended to cover not only the structures described herein for performing the function and their structural equivalents, but also equivalent structures. For example, although a nail and a screw have different structures, they are equivalent structures since they both perform the function of fastening. Claims that do not use the word “means” are not intended to fall under 35 USC Sect. 112, paragraph 6. Signals are typically electronic signals, but may be optical signals such as can be carried over a fiber optic line.

The foregoing description of the embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

We claim:

1. A linear temperature-control circuit comprising:
a comparator that receives a sensing voltage on a tap node and a reference voltage and generates a compare output;
a power supply input;
a voltage generator coupled to the power supply input, the voltage generator generating the reference voltage applied to the comparator;
a sensing node for connection between a heating element and a silicon-controlled rectifier (SCR);
a trigger generator, receiving the compare output from the comparator, and generating a trigger signal to the SCR, the trigger signal being applied to a trigger input of the SCR that controls current flow through the SCR to the heating element;
a sampling device connected between the sensing node and a protected node, for disconnecting the heating element from the protected node when the heating element is being heated, and for connecting the heating element to the protected node when the heating element is being sensed for temperature measurement;
a voltage network coupled between the protected node and the tap node and powered by the power supply input, the voltage network comprising:
a variable resistor having a first terminal and a second terminal and a tap node, wherein a resistance between the first terminal and the tap node is a variable resistance that is varied by a user;
a trailing series resistor, coupled between the second terminal of the variable resistor and the power supply input;
a parallel resistor coupled between the power supply input and the protected node,
whereby the voltage network varies the sensing voltage on the tap node to adjust heating of the heating element.

2. The linear temperature-control circuit of claim 1 wherein the sampling device is a diode that prevents current flow from the SCR through the voltage network to the comparator.

3. The linear temperature-control circuit of claim 1 wherein the sampling device is a switch that is opened when a heating current flows through the SCR to heat the heating element, and is closed for temperature measurement when the heating current is not applied to the heating element.

4. The linear temperature-control circuit of claim 2 wherein the voltage network further comprises:
a leading series resistor coupled between the protected node and the first terminal of the variable resistor,
wherein the parallel resistor is in parallel with a series of resistors that comprise the leading series resistor, the variable resistor, and the trailing series resistor.

5. The linear temperature-control circuit of claim 4 wherein the tap node is connected to the second terminal of the variable resistor.

6. The linear temperature-control circuit of claim 5 wherein the voltage generator comprises a voltage divider which comprises:
an upper resistor coupled between the power supply input and a reference input to the comparator having the reference voltage;
a lower resistor coupled between the reference input to the comparator and a ground node.

7. The linear temperature-control circuit of claim 5 wherein a resistance between the first terminal and the second terminal of the variable resistor is a fixed resistance, while the resistance to the tap node is variable.

8. The linear temperature-control circuit of claim 4 further comprising:
the heating element;
a heater power supply;
the SCR coupled between the heater power supply and the sensing node, the SCR disconnecting the heater power supply from the heating element when the heating element is being sensed for temperature measurement, the SCR having the trigger input for controlling activation of the SCR.

9. The linear temperature-control circuit of claim 8 wherein the heater power supply comprises an alternating-current (A.C.) power supply and wherein the power supply input is coupled to a direct-current (D.C) power supply.

10. The linear temperature-control circuit of claim 9 wherein the heating element has a positive temperature coefficient.

11. A linearly-controlled heater circuit comprising:
a circuit power supply input for receiving a direct current;
a heater power supply input for receiving an alternating current;
comparator means for comparing a sensing voltage on a first input to a reference voltage on a second input to generate a compare output;
voltage generator means, coupled to the circuit power supply input, for generating the reference voltage;
silicon-controlled rectifier (SCR) means, coupled between the heater power supply input and a heating element, for disconnecting the heater power supply input from the heating element when the heating element is being sensed for temperature measurement, the SCR means having a trigger input for controlling activation of the SCR means;
trigger circuit means, receiving the compare output from the comparator means, for generating a trigger signal applied to the trigger input of the SCR means;
isolation means, coupled between the heating element and a protected node, for isolating the heating element from the protected node when the heating element is being heated, and for connecting the heating element to the protected node when the heating element is being sensed for temperature measurement; and
voltage network means for generating the sensing voltage wherein a temperature of the heating element is linearly proportional to a variable resistance that is variable by a user,
whereby the voltage network means provides the variable resistance to linearly vary the temperature of the heating element in response to variations of the variable resistance by the user.

12. The linearly-controlled heater circuit of claim 11 wherein the voltage network means is coupled to the circuit power supply input, the voltage network means further comprising:
variable resistor means, having a first terminal and a second terminal and a tap node, for generating the variable resistance between the first terminal and the tap node that is varied by a user;
trailing series resistor means, coupled between the second terminal of the variable resistor means and the circuit power supply input, for producing a first fixed resistance;
parallel resistor means, coupled between the circuit power supply input and the protected node, for generating a second fixed resistance;
whereby the voltage network means varies the sensing voltage on the tap node to adjust heating of the heating element.

13. The linearly-controlled heater circuit of claim 12 wherein the tap node is connected to the second terminal of the variable resistor means.

14. The linearly-controlled heater circuit of claim 13 wherein the voltage network means further comprises:
leading series resistor means, coupled between the protected node and the first terminal of the variable resistor means, for generating a third fixed resistance,
wherein the parallel resistor means is in parallel with a series of resistors that comprise the leading series resistor means, the variable resistor means, and the trailing series resistor means.

15. The linearly-controlled heater circuit of claim 14 wherein the isolation means comprises diode means for preventing alternating current flow and for allowing direct current flow for temperature measurement.

16. The linearly-controlled heater circuit of claim 14 wherein the isolation means comprises a switch means for disconnecting the heating element from the protected node when the heating element is being heated, and for connecting the heating element to the protected node when the heating element is being sensed for temperature measurement.

17. A linearized temperature-control product comprising:
a heating body having a positive temperature coefficient;
a heater power supply for powering the heating body;
a silicon-controlled rectifier (SCR) coupled between the heater power supply and the heating body, the SCR disconnecting the heater power supply from the heating body during a temperature-sensing time period, the SCR having a trigger input;
a comparator for comparing a sensing voltage on a first input to a reference voltage on a second input to generate an output signal indicating a temperature of the heating body;
a sensing power supply;
an isolation device coupled between a protected node and the heating body to supply a sensing current into the heating body during the temperature-sensing time period;
a voltage generator coupled to the sensing power supply, the voltage generator generating the reference voltage;
a potentiometer coupled between the protected node and the first input of the comparator, the potentiometer powered by the sensing power supply and having a variable resistance that is variable by a user to linearly adjust temperature of the heating body,
whereby the potentiometer varies the sensing voltage applied to the comparator in response to the user varying the variable resistance.

18. The linearized temperature-control product of claim 17 wherein the potentiometer comprises:
a variable resistor having a first terminal and a second terminal and a tap node, wherein a resistance between the first terminal and the tap node is a variable resistance that is varied by a user;
wherein the tap node is connected to the first input of the comparator, the tap node having the sensing voltage;
a trailing series resistor, coupled between the second terminal of the variable resistor and the sensing power supply; and
a parallel resistor coupled between the sensing power supply and the protected node.

19. The linearized temperature-control product of claim 18 wherein the tap node is connected to the second terminal of the variable resistor.

20. The linearized temperature-control product of claim 18 further comprising:
a zero crossing synchronization circuit, coupled between the comparator and the trigger input of the SCR;
wherein the isolation device is a switch or a diode.
